(19) United States
(12) Patent Application Publication
(10) Pub. No.: US 2020/0175939 A1
(43) Pub. Date: Jun. 4, 2020

(54) LIQUID CRYSTAL DISPLAY DEVICE

(71) Applicant: Panasonic Liquid Crystal Display Co., Ltd., Hyogo (JP)

(72) Inventor: Teruhisa NAKAGAWA, Hyogo (JP)

(21) Appl. No.: 16/206,140

(22) Filed: Nov. 30, 2018

(51) Int. Cl. G09G 3/36; G02F 1/1362; G02F 1/1343; H01L 27/146; H01L 29/786

(52) U.S. Cl. CPC G09G 3/3688; G09G 3/3648; H01L 29/78633; G02F 1/134336; H01L 27/14603; G02F 1/13624

(57) ABSTRACT

A liquid crystal display device according to the present disclosure is provided. The liquid crystal display includes: a data signal line extending in a first direction, and a pixel electrode electrically connected to the data signal line through a thin film transistor. The pixel electrode includes at least one comb part extending in the first direction. The comb part includes a bend portion in a middle area that is between a first end and a second end of the comb in the first direction. Also, a shortest distance between the data signal line and the bend portion of the comb part is shorter than a shortest distance between the data signal line and the first end of the comb part and shorter than a shortest distance between the data signal line and the second end of the comb part.

### TECHNICAL FIELD

The present invention relates to a liquid crystal display device.

### BACKGROUND

A liquid crystal display device includes a data signal line extending in a column direction, and a pixel electrode electrically connected to the data signal line through a thin film transistor. The pixel electrode includes at least one comb part extending in the column direction. The comb part includes a bend portion in its middle area in order to surpass color shifts of an image when viewed from oblique angle. The data signal line is in parallel with the comb part and includes a bend portion in its middle area in order to enhance an aperture ratio of the liquid crystal display device.

### SUMMARY

When the data signal line includes the bend portion, a disadvantage could happen due to the bend portion. For example, when an initial alignment is given to a liquid crystal layer by means of a rubbing process, a step is formed in an alignment film above the bend portion. Due to this, the initial alignment around the step can be improved. (In the rubbing process, a rubbing cloth rubs an alignment film.)

This present disclosure provides a liquid crystal display device in which the initial alignment is improved by improving a layout of the data signal line.

To solve the above problem, a liquid crystal display device according to the present disclosure includes: a data signal line extending in a first direction, and a pixel electrode electrically connected to the data signal line through a thin film transistor, wherein the pixel electrode includes at least one comb part extending in the first direction, the comb part includes a bend portion in a middle area that is between a first end and a second end of the comb in the first direction, and a shortest distance between the data signal line and the bend portion of the comb part is shorter than a shortest distance between the data signal line and the first end of the comb part and shorter than a shortest distance between the data signal line and the second end of the comb part.

### BRIEF DESCRIPTION OF THE DRAWINGS

FIG. 1 is a view illustrating a schematic configuration of a liquid crystal display device according to a first exemplary embodiment;

FIG. 2 is a plan view illustrating a configuration of a pixel in the liquid crystal display device of the first exemplary embodiment;

FIG. 3 is a sectional view taken along a line III-III in FIG. 2;

FIG. 4 is a plan view illustrating a configuration of a pixel in the liquid crystal display device of a second exemplary embodiment; and

FIG. 5 is a sectional view taken along a line V-V in FIG. 4.

### DETAILED DESCRIPTION

### First Embodiment

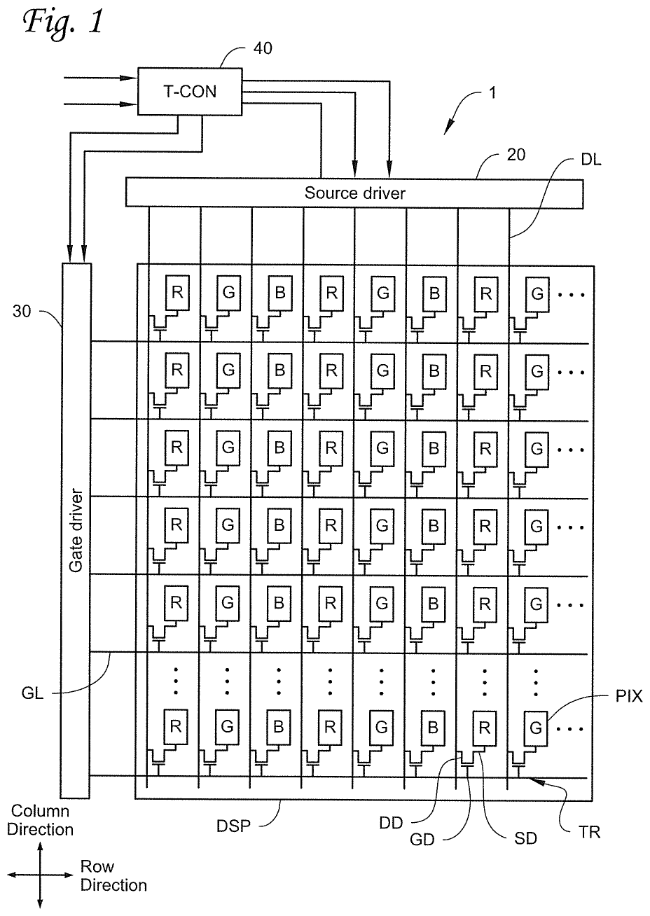

FIG. 1 is a view illustrating a schematic configuration of a liquid crystal display device 1 according to a first exemplary embodiment. The liquid crystal display device 1 shown in FIG. 1 displays a color image or a monochrome image in an image display region DSP. The liquid crystal display device 1 is an example of an image display device that displays a still image or a moving image.

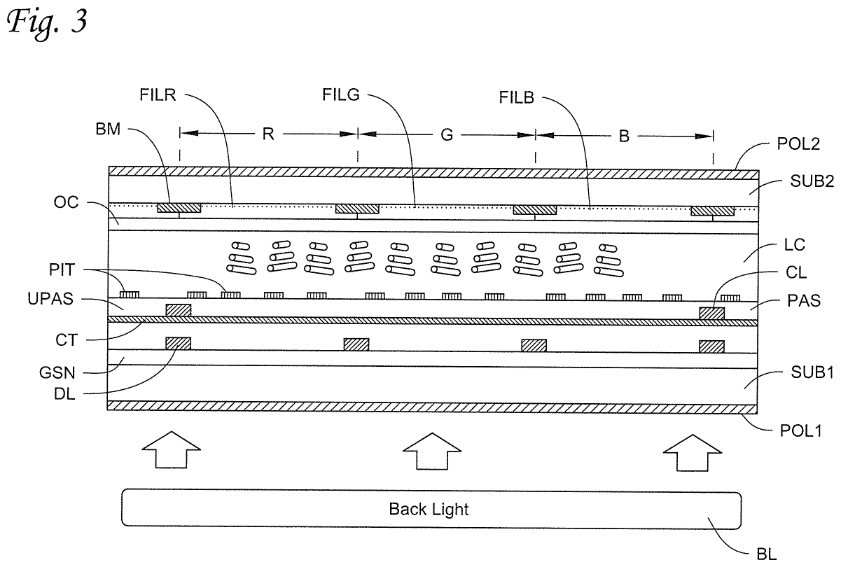

The liquid crystal display device 1 includes a liquid crystal cell which includes a liquid crystal layer LC disposed between a pair of transparent substrates SUB1, SUB2, and a pair of polarizers POL1, POL2 sandwiching the liquid crystal cell (see, FIG. 3). One of the pair of transparent substrates is a thin film transistor (TFT) substrate SUB1 on which thin film transistors TR and wirings are disposed. The other of the pair of transparent substrates is a color filter (CF) substrate SUB2 on which color filters are disposed. For example, a system for driving the liquid crystal display device 1 is a transverse electric field system such as an In Plane Switching system (IPS) or a Fringe Field Switching system (FFS). However, a system for driving the liquid crystal display device 1 also can be a Vertical Alignment system or a Twisted Nematic system.

As illustrated in FIG. 1, liquid crystal display device 1 includes a plurality of pixels PIX arranged in a matrix. Image display region DSP in which the image is displayed is constructed with the plurality of pixels PIX arranged in a matrix. A transistor TR, a pixel electrode PIT, and a common electrode CT are provided in each of the plurality of pixels PIX (see, FIG. 3). The transistor TR is a thin film transistor, and includes gate electrode GD and a pair of conductive electrodes DD, SD. The pair of conductive electrodes consist of a drain electrode DD and a source electrode SD.

The liquid crystal display device 1 includes a plurality of data signal lines DL extending in a first direction and a plurality of gate signal lines GL extending in a second direction that is different from the first direction. In FIG. 1, the plurality of data signal lines DL extend in a column direction and the plurality of gate signal lines GL extend in a row direction.

The plurality of data signal lines DL are provided at a corresponding boundary between two pixels PIX adjacent to each other in the row direction. The plurality of gate signal lines GL are provided at a corresponding boundary between two pixels PIX adjacent to each other in the column direction. In this case, the plurality of pixels PIX are sectioned by the plurality of data signal lines DL and the plurality of gate signal lines GL.

Each data signal line DL is connected to the plurality of transistors TR of pixels PIX arranged in the column direction. Specifically, each data signal line DL is connected to the drain electrodes DD of those transistors TR.

Each gate signal line GL is connected to the plurality of transistors TR of pixels PIX arranged in the row direction. Specifically, each gate signal line GL is connected to the gate electrodes GD of those transistors TR.

In each pixel PIX, the source electrode SD of the transistor TR is electrically connected to a pixel electrode PIT. As shown in FIG. 3, each pixel electrode PIT faces a common electrode CT. In this embodiment, single common electrode CT is provided over the plurality of pixels PIX. Specifically, single common electrode CT is provided over all pixels PIX in the image display region DSP. That is, common electrode CT is one planar electrode common to all pixels PIX, and is formed over entire image display region DSP. In each pixel PIX, a capacitor is formed between the pixel electrode PIT and the common electrode CT.

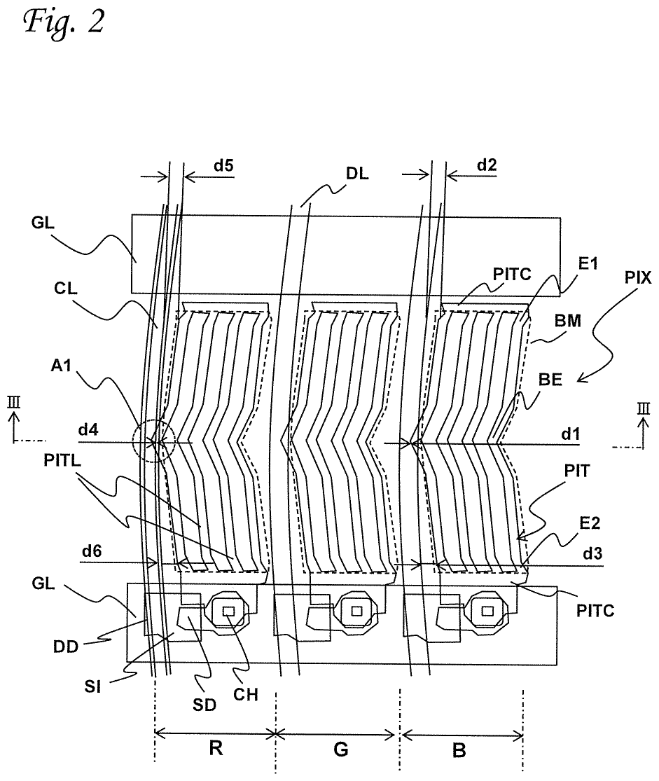

As shown in FIG. 2, a plurality of common lines CL extending in the column direction is provided at a boundary between two pixels PIX adjacent to each other in the row direction. The plurality of common lines CL are provided in order to supply a common voltage to the common electrode CT. each of the plurality of common lines CL are in parallel with the plurality of the data signal lines DL.

The plurality of data signal lines DL are connected to a source driver 20, and the plurality of gate signal lines GL are connected to a gate driver 30. The source driver 20 and the gate driver 30 are for example a driver Integrated Circuit (IC), and mounted on flexible print substrates as Chip On Film (COF). The flexible print substrate on which the source driver 20 is mounted is connected to terminals formed on a peripheral area which is outside of the image display region DSP, through an anisotropic conductive film.

In response to a selection of gate signal lines GL by the gate driver 30, the source driver 20 supplies, to a corresponding data signal line DL, data voltage corresponding to the video signal input from an image processor (timing controller T-Con) 40.

The gate driver 30 selects pixels PIX in which the video signal is written according to a timing signal input from the image processor 40, and supplies gate-on voltage turning on the transistor TR of selected pixel PIX to the gate signal line GL. Consequently, the data voltage is supplied to pixel electrodes PIT of selected pixels PIX through transistors TR.

In this way, when the gate-on voltage is supplied from the gate driver 30 to a gate signal line GL, transistors TR of selected pixels PIX are turned on, and the data voltage is supplied from a data signal line DL connected to transistor TR to a pixel electrode PIT. An electric field is generated in a liquid crystal layer LC due to a difference between the data voltage supplied to the pixel electrode PIT and the common voltage supplied to the common electrode CT. An alignment state of liquid crystal molecules of the liquid crystal layer in each pixel PIX is changed by the electric field, and transmittance of light of backlight BL passing through liquid crystal display device 1 is controlled in each pixel PIX (see FIG. 3). Consequently, the desired image is displayed in the display region (pixel region) of the liquid crystal display device 1.

A structure of the liquid crystal display device 1 will be described with reference to FIGS. 2 and 3. FIG. 2 is a plan view illustrating a configuration of a pixel PIX in the liquid crystal display device 1 of the first exemplary embodiment. FIG. 3 is a sectional view taken along a line III-III in FIG. 2.

As illustrated in FIG. 2, a plurality of slits are formed in each pixel electrode PIT, and each pixel electrode PIT includes a plurality of comb parts PITL extending in the column direction. In the first exemplary embodiment, each pixel electrode PIT includes four comb parts PITL. Ends E1, E2 in the column direction of the four comb parts PITL are connected by a connection electrode PITC. The connection electrode PITC extends along the row direction in a vicinity of gate signal line GL. All comb parts PITL in each pixel electrode PIT are formed in parallel and are spaced apart from each other. Each comb part PITL is formed into a substantial U-shape having a bend portion BE in a central portion. The central portion is located between both ends E1, E2 in the column direction. In FIG. 2, the bend portion BE consists of a part protruding most in the row direction among the comb part PITL. Owing to the bend portion BE, color shifts of an image can be surpassed when viewed from oblique angle (multi-domain effect).

In the first exemplary embodiment, each data signal line DL is nonparallel with the comb part PITL. Namely, each data signal line DL does not include a bend portion.

As shown in FIG. 2, a distance d1 between the data signal line DL and the bend portion BE of the comb part PITL is shorter than a distance d2, d3 between the data signal line DL and the both ends E1, E2 of the comb part PITL. In FIGS. 2 and 3, the data signal line DL partially overlaps with the bend portion BE of the comb part PITL. In this case, the distance d1 is zero. The data signal line DL is offset from the first and second ends E1, E2 of the comb part PITL. In other words, the data signal line DL does not overlap the both ends E1, E2 of the comb part PITL. the distance d2, d3 is for example 10-20 um.

A plurality of common signal lines CL are electrically connected to the common electrode CT. The plurality of common signal lines CL extend in the column direction, and at least partially overlap with the plurality of data signal lines DL respectively. In this embodiment, one common signal line CL is provided in every three columns (pixel column). Each common signal line CL is located above a corresponding data signal line DL that supplies data voltage with pixels PIX corresponding to a blue color. The plurality of common signal lines CL are in parallel with the plurality of data signal lines DL, and are nonparallel with comb parts PITL.

As shown in FIG. 2, a distance d4 between the common signal line CL and the bend portion BE of the comb part PITL is shorter than a distance d5, d6 between the common signal line CL and the both ends E1, E2 of the comb part PITL. In FIGS. 2 and 3, the common signal lines CL partially overlap with the bend portion BE of the comb part PITL. In this case, the distance d4 is zero. The common signal line CL is offset from the first and second ends E1, E2 of the comb part PITL. In other words, the common signal line CL does not overlap the both ends E1, E2 of the comb part PITL. the distance d5, d6 is for example 10-20 um.

Next, a section of the liquid crystal display device 1 will be explained.

Referring to FIGS. 2 and 3, in TFT substrate, a plurality of gate signal lines GL are formed on a transparent substrate SUB1. The gate signal lines GL are formed by a metallic material mainly containing aluminum (Al), molybdenum (Mo), titanium (Ti), or copper (Cu), or a plurality of laminated layers thereof.

A gate insulating layer GSN is formed so as to cover the plurality of gate signal lines GL. The gate insulating layer GSN can be made of silicon nitride SiN. Semiconductor layers SI are formed on the gate insulating layer GSN. The data signal line DL mainly containing copper Cu and the drain electrode DD and the source electrode SD, which constitute the thin film transistor TR, are formed on the semiconductor layer SI. The drain electrode DD is electrically connected to the data signal line DL.

An intermediate insulating layer PAS is formed so as to cover the plurality of data signal lines DL, the drain electrode DD, and the source electrode SD. The intermediate insulating layer PAS can be made of silicon nitride SiN or silicon dioxide SiO₂.

A common electrode CT is formed on the intermediate insulating layer PAS. The common electrode CT is made of a transparent electrode material ITO. For example, the common electrode CT can be made of indium tin oxide or indium zinc oxide. The common signal lines CL through which common voltage Vcom is supplied to the common electrode CT is formed on the common electrode CT. The common signal lines CL are made of a metallic material mainly containing copper Cu.

An upper insulating layer UPAS is formed so as to cover the common electrode CT and the common signal lines CL. The upper insulating layer UPAS can be made of silicon nitride SiN. A plurality of Pixel electrodes PIT is formed on the upper insulating layer UPAS. The plurality of Pixel electrodes PIT are made of a transparent electrode material ITO. Each pixel electrode PIT is electrically connected to the source electrode SD through a contact hole CH (see FIG. 2) formed in the upper insulating layer UPAS and the intermediate insulating layer PAS. Although not illustrated, an alignment film is formed so as to cover the plurality of pixel electrodes PIT. A polarizing plate POL1 is formed on a side of the transparent substrate SUB1 facing the back light BL. The common electrode CT is opposed to the pixel electrode PIT. In the configuration of FIGS. 2 and 3, the common electrode CT is disposed in a lower layer while the pixel electrodes PIT are disposed in an upper layer. Alternatively, the pixel electrodes PIT may be disposed in the lower layer while the common electrode CT is disposed in the upper layer.

In a color filter (CF) substrate, colored portions FILR, FILG, FILB and a black matrix BM are formed on the transparent substrate SUB2. For example, colored portions FILR, FILG, FILB are formed by colored layers of red, green, and blue pigment-dispersion resists, and the black matrix BM is made of a metallic material or a resin material in which black pigment is used. An overcoat film OC is formed so as to cover the colored portions FILR, FILG, FILB and the black matrix BM, and an alignment film is formed on the overcoat film OC. A polarizing plate POL2 is formed on a side of the transparent substrate SUB2 closer to an observer.

The black matrix BM is disposed in boundary areas between the plurality of pixels PIX. The black matrix BM overlaps with the plurality of data signal lines DL and a plurality of gate signal lines GL. Moreover, the black matrix BM also overlaps a superposed area A1 where the data signal line DL overlaps with the bend portion BE of the comb part PIXL.

According to the first embodiment, a distance d1 between the data signal line DL and the bend portion BE of the comb part PITL is shorter than a distance d2, d3 between the data signal line DL and the both ends E1, E2 of the comb part PITL. With this, a layout of the data signal line DL is improved.

In the first exemplary embodiment, each data signal line DL is nonparallel with the comb part PITL and does not include a bend portion. Owing to this configuration, in a rubbing process, it becomes difficult for a step to be formed in an alignment film due to the bend portion. As a result, an initial alignment to a liquid crystal layer LC can be improved.

According to the first embodiment, a distance d4 between the common signal line CL and the bend portion BE of the comb part PITL is shorter than a distance d5, d6 between the common signal line CL and the both ends E1, E2 of the comb part PITL. With this, a layout of the common signal line CL is improved.

In the first exemplary embodiment, each common signal line CL is nonparallel with the comb part PITL and does not include a bend portion. Owing to this configuration, in a rubbing process, it becomes difficult for a step to be formed in an alignment film due to the bend portion. As a result, an initial alignment to a liquid crystal layer LC can be improved.

### Second Exemplary Embodiment

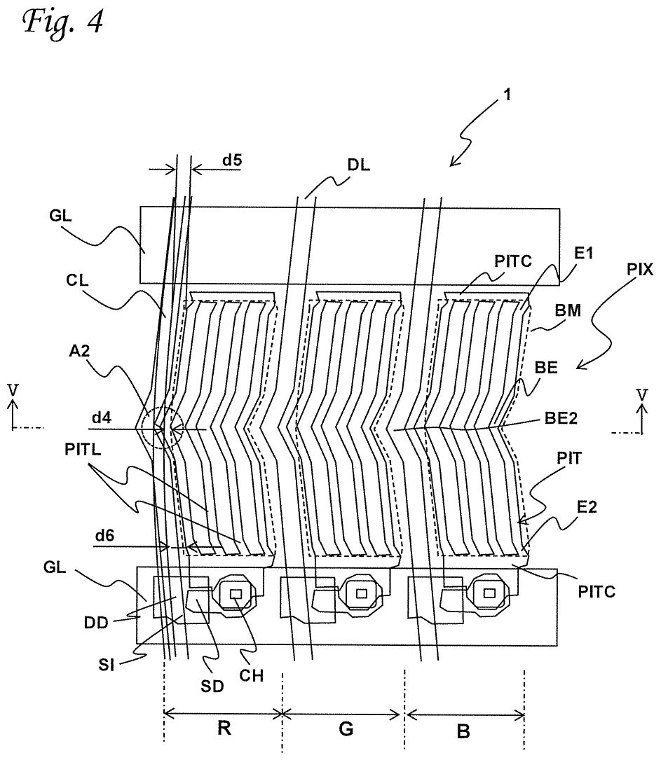

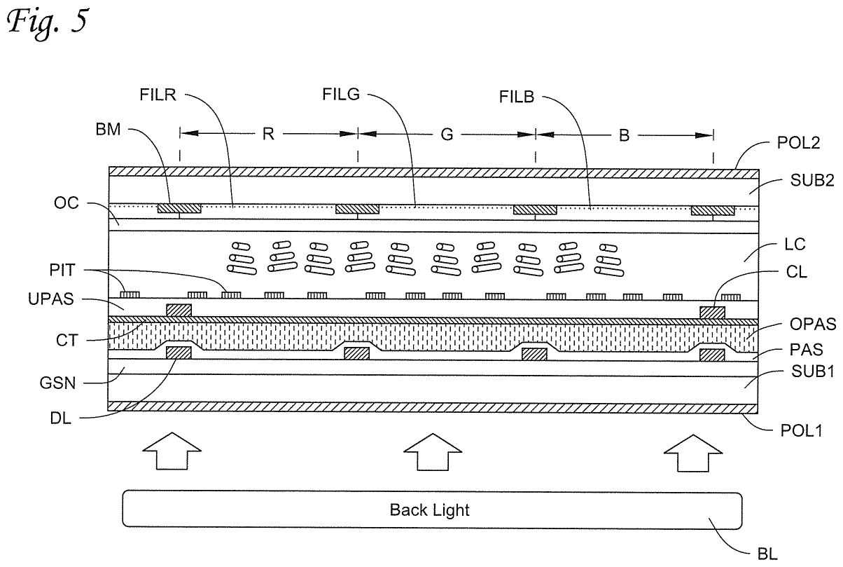

A liquid crystal display device 1 according to a second exemplary embodiment will be described below with reference to FIGS. 4 and 5. FIG. 4 is a plan view illustrating a configuration of a pixel PIX in the liquid crystal display device 1 of the second exemplary embodiment. FIG. 5 is a sectional view taken along a line V-V in FIG. 4.

In the second embodiment, an organic insulating layer OPAS is further formed on the intermediate insulating layer PAS (see FIG. 5), and a shape of the data signal line DL is different from that of the first embodiment (see FIG. 4). Other elements are similar to those of the first embodiment.

As shown in FIGS. 4 and 5, the organic insulating layer OPAS is formed on the intermediate insulating layer PAS. The organic insulating layer OPAS can be made of a photosensitive organic material mainly containing acryl. The organic insulating layer OPAS can be thicker than the intermediate insulating layer PAS. Therefore, any steps formed due to the data signal line DL below the organic insulating layer OPAS can almost be eliminated. Owing to this, data signal line DL is in parallel with the comb part PITL of the pixel electrode PIT, and includes a bend portion BE2. This is because even if the data signal line DL includes the bend portion BE2, the organic insulating layer OPAS can minimize steps due to the bend portion BE2.

On the other hand, each data signal line DL is nonparallel with the plurality of common signal lines CL. That is to say, each common signal line CL does not include any bend portion while each data signal line DL includes the bend portion BE2.

In this embodiment, a distance d4 between the common signal line CL and the bend portion BE of the comb part PITL is shorter than a distance d5, d6 between the common signal line CL and the both ends E1, E2 of the comb part PITL. In FIGS. 4 and 5, each of the common signal lines CL partially overlaps with the bend portion BE of the comb part PITL. The common signal line CL is offset from the first and second ends E1, E2 of the comb part PITL.

The data signal line DL does not overlap the comb part PITL of the pixel electrode PIT. Specifically, the data signal line DL does not overlap a superposed area A2 where the common signal line CL overlaps with the bend portion BE of the comb part PIXL.

1. A liquid crystal display device having a plurality of pixels arranged in a matrix, comprising:
a data signal line extending in a first direction; and
a pixel electrode electrically connected to the data signal line through a thin film transistor,
wherein the pixel electrode includes at least one comb part extending in the first direction,
the comb part includes a bend portion in a middle area that is between a first end and a second end of the comb part in the first direction, and
the data signal line partially overlaps with the bend portion of the comb part.

2. The liquid crystal display device according to claim 1, wherein the data signal line is nonparallel with the comb part.

3. (canceled)

4. The liquid crystal display device according to claim 1, further comprising:
a black matrix disposed in boundary areas between the plurality of pixels, wherein the black matrix also overlaps a superposed area where the data signal line overlaps with the bend portion of the comb part.

5. The liquid crystal display device according to claim 1, wherein the data signal line is offset from the comb part at the first end of the comb part and at the second end of the comb part.

6. The liquid crystal display device according to claim 1, further comprising;
a common electrode opposed to the pixel electrode; and
a common signal line, which supplies a common signal to the common electrode, that extends in the first direction and at least partially overlaps with the data signal line.

7. The liquid crystal display device according to claim 6, wherein
a shortest distance between the common signal line and the bend portion of the comb part is shorter than a shortest distance between the common signal line and the first end of the comb part and shorter than the shortest distance between the data signal line and a second end of the comb part.

8. The liquid crystal display device according to claim 6, wherein the common signal line is nonparallel with the comb part.

9. The liquid crystal display device according to claim 6, wherein
the common signal line partially overlaps with the bend portion of the comb part.

10. The liquid crystal display device according to claim 9, wherein
the common signal line is offset from the comb part at the first end of the comb part and at the second end of the comb part.

11. A liquid crystal display device having a plurality of pixels arranged in a matrix, comprising:
a data signal line extending in a first direction;
a pixel electrode electrically connected to the data signal line through a thin film transistor;
a common electrode opposed to the pixel electrode; and
a common signal line, which supplies a common signal to the common electrode, that extends in the first direction,
wherein the pixel electrode includes at least one comb part extending in the first direction,
the comb part includes a bend portion in a middle area that is between a first end and a second end of the comb part in the first direction, and
the common signal line partially overlaps with the bend portion of the comb part.

12. The liquid crystal display device according to claim 11, wherein
the common signal line is nonparallel with the comb part.

13. The liquid crystal display device according to claim 12, wherein the data signal line is nonparallel with the comb part.

14. (canceled)

15. The liquid crystal display device according to claim 11, wherein the data signal line is offset from the comb part.

16. The liquid crystal display device according to claim 11, wherein the common signal line at least partially overlaps with the data signal line.

17. The liquid crystal display device according to claim 11, wherein a shortest distance between the common signal line and the bend portion of the comb part is shorter than a shortest distance between the common signal line and the first end of the comb part and shorter than a shortest distance between the common signal line and the second end of the comb part.

18. The liquid crystal display device according to claim 1, wherein a shortest distance between the data signal line and the bend portion of the comb part is shorter than a shortest distance between the data signal line and the first end of the comb part and shorter than a shortest distance between the data signal line and the second end of the comb part.
